(19) United States
(12) Patent Application Publication
(10) Pub. No.: US 2002/0064713 A1
(43) Pub. Date: May 30, 2002

(54) Strong phase shift mask substrates

(76) Inventor: Richard D. Schinella, Saratoga, CA (US)

Correspondence Address: LSI Logic Corporation, 1551 McCarthy Blvd., M/S: D-106 Patent Department, Milpitas, CA, 95035, US

(21) Appl. No.: 09/725,380

(22) Filed: Nov. 29, 2000

(51) Int. Cl. G03F 9/00; G03C 5/00; C08F 2/38

(52) U.S. Cl. 430/5; 430/322; 430/323; 427/509; 427/518

(57) ABSTRACT

A method of forming a strong phase shift mask substrate. A substrate is introduced into a deposition chamber. The substrate has a surface, and is transmissive to electromagnetic radiation of a desired wavelength. A first precursor having at least a first component and a second component is introduced, and covers the surface of the substrate to a thickness of one molecular layer of the first precursor. The excess of the first precursor is removed from within the deposition chamber. A second precursor having at least a third component and a fourth component is introduced. The second precursor attaches to the first precursor. The excess of the second precursor is removed from within the deposition chamber. The first precursor is reacted with the second precursor to form a first monolayer of the first component and the third component on the surface of the substrate. The first monolayer is operable to cause a first phase shift in the electromagnetic radiation of the desire wavelength. Because the first monolayer is deposited on the substrate at a known thickness, the first monolayer produces a known phase shift in the electromagnetic radiation of the desired wavelength. Thus, the method of the present invention provides the ability to very finely tune the phase shifting characteristics of the strong phase shift mask substrate. In this manner the strong phase shift mask substrate may be used for very fine dimension sub wavelength photolithography.

### FIELD

This invention relates to the field of semiconductor processing. More particularly the invention relates to sub wavelength photolithography techniques.

### BACKGROUND

As integrated circuits continue to shrink in size, the processes by which they are formed are increasingly limited by fundamental physical laws. For example, in forming structures, such as gate structures in a metal oxide semiconductor device, that are less than about a quarter micron in length, or in other words less than about 250 nanometers long, the ability of the radiation used to pattern the structure during the photolithographic process is seriously challenged. Typical deep sub micron photolithography processes use deep ultra violet radiation with a wavelength of about 248 nanometers to expose the photoresist used to pattern the structures. Unfortunately, a beam of light with a wavelength of 248 nanometers has difficulty in resolving the closely spaced features in a masking pattern that is not appreciably greater than the wavelength of the light. Thus, the processes used to form integrated circuits must necessarily change as even smaller device features, such as 100 nanometer gate lengths, are desired.

One method of forming devices with smaller features is to use electromagnetic radiation with smaller wavelengths during the photolithography process. For example, electromagnetic radiation with a wavelength of 193 nanometers provides the ability to pattern features that are about twenty percent smaller than those patterned with electromagnetic radiation having a wavelength of 248 nanometers. However, moving to steppers and other exposure tools that utilize 193 nanometer technology is still insufficient, of itself, to produce 100 nanometer features. Radiation with even shorter wavelengths, such as 157 nanometers, presents serious cost considerations and other technical challenges. Thus, other improvements to the photolithography process are required.

Some of these other improvements provide for the ability to accomplish so-called sub wavelength patterning of photoresist. By this it is meant that the techniques employed provide the ability for the electromagnetic radiation to pattern features that have dimensions that are smaller than the wavelength of the electromagnetic radiation so employed. One such technique is the use of strong phase shift masks.

A strong phase shift mask makes use of the interference that is produced between waves of electromagnetic radiation that are out of phase. By use of this interference property, very small feature sizes can be patterned. Unfortunately, strong phase shift masks that have finely tuned characteristics are difficult to create. What is needed, therefore, is a system for creating strong phase shift masks in a way by which they can be very finely tuned for optical performance.

### SUMMARY

The above and other needs are met by a method of forming a strong phase shift mask substrate. A substrate is introduced into a deposition chamber. The substrate has a surface, and is transmissive to electromagnetic radiation of a desired wavelength. A first precursor having at least a first component and a second component is introduced, and covers the surface of the substrate to a thickness of one molecular layer of the first precursor. The excess of the first precursor is removed from within the deposition chamber. A second precursor having at least a third component and a fourth component is introduced. The second precursor attaches to the first precursor. The excess of the second precursor is removed from within the deposition chamber. The first precursor is reacted with the second precursor to form a first monolayer of the first component and the third component on the surface of the substrate. The first monolayer is operable to cause a first phase shift in the electromagnetic radiation of the desire wavelength.

Because the first monolayer is deposited on the substrate at a known thickness, the first monolayer produces a known phase shift in the electromagnetic radiation of the desired wavelength. Thus, the method of the present invention provides the ability to very finely tune the phase shifting characteristics of the strong phase shift mask substrate. In this manner the strong phase shift mask substrate may be used for very fine dimension sub wavelength photolithography.

In various preferred embodiments, the first monolayer is etched to form a desired pattern in the first monolayer. The etch is preferably an anisotropic etch, or an etch using a process such as liquid chemical etching, gas phase etching, plasma based etching, sputter etching, ion beam etching, and molecular beam etching. The first monolayer may be activated with a process that enhances the etchability of the first monolayer, but which does not enhance the etchability of the substrate. The activating process may comprise a chemical treatment or a physical treatment.

In a most preferred embodiment, the method as described above is iteratively repeated to form a first layer having a thickness of a predetermined number of monolayers, which preferably produces a desired phase shift in the electromagnetic radiation of the desired wavelength.

In a further embodiment, a third precursor having at least a fifth component and a sixth component is introduced, and the excess of the third precursor is removed from the deposition chamber. A fourth precursor having at least a seventh component and an eighth component is introduced. The fourth precursor attaches to the third precursor, and the excess of the fourth precursor is removed from the deposition chamber. The third precursor is reacted with the fourth precursor to form a second monolayer of the fifth component and the seventh component on the first monolayer. The second monolayer is operable to cause a second phase shift in the electromagnetic radiation of the desired wavelength.

The further embodiment described above is preferably iteratively repeated to form a second layer having a thickness of a predetermined number of monolayers. Different numbers of monolayers of the first layer and different numbers of monolayers of the second layer are preferably deposited in a predetermined sequence to form a composite layer on the substrate, where the composite layer has predetermined optical characteristics and predetermined etch characteristics.

In another aspect, the invention comprehends a strong phase shift mask substrate formed of a substrate that is transmissive to electromagnetic radiation of a desire wavelength, and an optically transmissive layer. The optically transmissive layer is formed of a predetermined number of at least one type of individually deposited monolayers, where the optically transmissive layer causes a predetermined phase shift in the electromagnetic radiation of the desired wavelength.

### BRIEF DESCRIPTION OF THE DRAWINGS

Further advantages of the invention are apparent by reference to the detailed description when considered in conjunction with the figures, which are not to scale so as to more clearly show the details, wherein like reference numbers indicate like elements throughout the several views, and wherein:

FIG. 1 is a cross sectional view of a substrate and a first precursor,

FIG. 2 is a cross sectional view of the substrate, the first precursor, and a second precursor,

FIG. 3 is a cross sectional view of the substrate and a first monolayer formed from the first precursor and the second precursor,

FIG. 4 is a cross sectional view of the substrate, the first monolayer, and a third precursor,

FIG. 5 is a cross sectional view of the substrate, the first monolayer, the third precursor, and a fourth precursor,

FIG. 6 is a cross sectional view of the substrate, the first monolayer and a second monolayer formed from the third precursor and the fourth precursor,

FIG. 7 is a cross sectional view of the substrate and a stack of first monolayers and second monolayers, and

FIG. 8 is a cross sectional view of the substrate, a patterned first monolayer, and a patterned second monolayer.

### DETAILED DESCRIPTION

Strong phase shift masks are used to pattern features of an integrated circuit that would tend to be, without the use of a strong phase shift mask, either disposed too closely together or at too small a size to be resolved with the wavelength of the light used to pattern the image. Strong phase shift masks make use of the interference that occurs between adjacent waves of electromagnetic radiation that are out of phase, one with the other. The sets of out of phase waves reduce the apparent intensity of the radiation in the overlap region between the wave sets to an extent that the intensity is insufficient to alter, or in other words expose, the photoresist on which it impinges. Thus, by having a first field, in which the radiation in passed in a reference or zero degree phase, placed between two other fields, in which the radiation is passed in an alternate or 180 degree phase, the interference created by the combination of the waves that are out of phase on either side of the first field, results in a reduced width of radiation through the first field that has sufficient intensity to expose the photoresist. Thus, the width of the radiation pattern passed by the first field that has sufficient intensity to expose the photoresist is narrower than the width of the first field itself. In this manner, features that are narrower than the wavelength of the radiation can be resolved. In addition, the resolved features can be narrower than the field used to resolve them.

The technique described above generally describes how a strong phase shift mask may be used to pattern a negative photoresist, where the first field is used to expose the photoresist, causing it to cross link and remain after developing. This same technique can be used in a slightly different manner with positive photoresist, where two out of phase fields are disposed adjacent each other, and create a radiation extinction zone in the interference at their interface. By adjusting the degree to which the two fields are out of phase, and other parameters, the width of the extinction zone between them can be set to a desired value. Thus, without any other means present on the mask, a narrow feature defined by the extinction zone on the strong phase shift mask can be left unexposed in the positive photoresist, which remains after developing.

The waves of out of phase radiation are preferably formed by fields that have different apparent optical path lengths. This may be accomplished by selectively etching fields in the strong phase shift mask substrate. However, this process tends to be difficult to control to a fine degree. Because the desired depth of etch is relatively small, and even small variations in the desired depth of etch effect the phase of the radiation, it is relatively difficult to etch the desired fields of the strong phase shift mask substrate to the precise depth desired, and in such a manner that the precise depth is achieved with a high degree of uniformity across the entire surface of the strong phase shift mask substrate.

Thus, the present invention creates optical paths of finely controllable apparent lengths, by depositing optically transmissive layers of predetermined thicknesses and predetermined properties, and selectively removing layers of known thicknesses, to produce a strong phase shift mask substrate having well controlled phase shift regions.

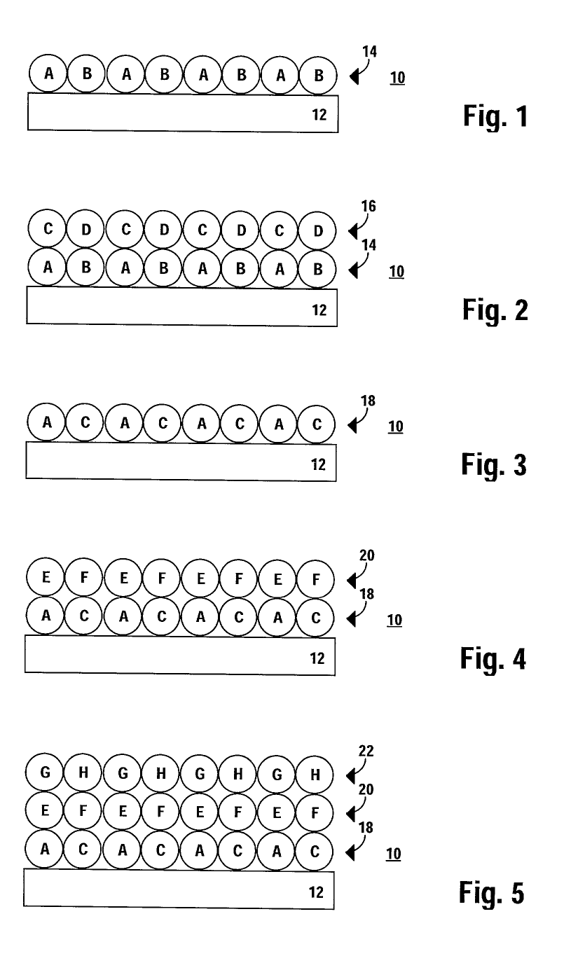

Referring now to FIG. 1, there is depicted a strong phase shift mask substrate 10, which at the stage of the processing depicted comprises a substrate 12 and a first precursor layer 14. The substrate 12 is preferably formed of a highly transmissive material, such as quartz or sapphire. The precursor layer 14 is preferably deposited in an atomic layer deposition chamber, such as a Pulsar 2000 manufactured by ASM Microchemistry Ltd. of Espoo, Finland, or the Lynx2 manufactured by Genus Inc. of Sunnyvale, Calif.

As depicted in FIG. 1, the first precursor layer 14 is formed of a binary material, or in other words, a material that has two discernable components, A and B. The components A and B of the first precursor layer 14 may represent a single atomic species each, or more complex molecules, or a combination of the two. Although it is preferred that the first precursor layer 14 is formed of a binary compound as depicted, in alternate embodiments the first precursor layer 14 is formed of a ternary or quaternary compound. Depending upon the composition of the resultant layer desired, the first precursor layer 14 may be formed of a single component. As mentioned briefly above, as used herein the various components A, B, C, D, etc. of the various precursors described represent a component that may be thought of as a single reaction group, whether that single reaction group be a single atom or a relatively large and complex molecule. This concept is built upon and becomes more clear throughout the following discussion.

The first precursor layer 14 is preferably deposited on the surface of the substrate 12 such that the surface of the substrate 12 is completely saturated with the first precursor material. The first precursor material is introduced to the substrate 12 within the reaction chamber of the atomic layer deposition tool so used. The first precursor may be introduced as a pure gas, or may be introduced in an evaporated form within a carrier gas, or may be evaporated from a solid source within the chamber, where the evaporant is brought to the substrate 12 by a carrier gas. After the surface of the substrate 12 is completely saturated, the excess first precursor material is removed from the deposition chamber, such as by drawing a vacuum within the environment of the reaction chamber of the deposition tool.

A second precursor layer 16 is deposited on top of the first precursor layer 14, as depicted in FIG. 2. The second precursor layer 16 is preferably deposited according to a substantially similar method as that used for the first precursor layer 14. As depicted in FIG. 2, the second precursor layer 14 is formed of a binary material, or in other words, a material that has two discernable components C and D. The components C and D of the second precursor layer 16 may represent a single atomic species each, or more complex molecules, or a combination of the two. Although it is preferred that the second precursor layer 16 is formed of a binary compound as depicted, in alternate embodiments the second precursor layer 16 is formed of a ternary or quaternary compound. Depending upon the composition of the resultant layer desired, the second precursor layer 16 may also be formed of a single component.

The second precursor layer 16 is preferably deposited on the first precursor layer 14 such that each of the available bonding sites of the first precursor layer 14 is positioned with a corresponding attracted molecule of the second precursor layer 16. The second precursor material is also introduced to the substrate 12 within the reaction chamber of the atomic layer deposition tool so used. As described above, the second precursor may be introduced as a pure gas, or may be introduced in an evaporated form within a carrier gas. After all of the bonding sites of the first precursor layer 14 are taken, the excess second precursor material is removed from the deposition chamber, such as by drawing a vacuum within the environment of the reaction chamber of the deposition tool.

The strong phase shift mask substrate 10 is then subjected to some type of energy infusion or other condition that drives the reaction kinetics between the first precursor layer 14 and the second precursor layer 16 to form the first monolayer A-C 18 as depicted in FIG. 3. The energy infusion may be provided in manner such as heat, light, or plasma. Another condition that may adjust the equilibrium to favor the formation of the first monolayer A-C 18 is either an increase or a decrease in pressure.

It is appreciated that the simplified discussion as presented in regard to the FIGS. 2 and 3 may describe an intermediate situation that does not actually exist. For example, the ordered arrangement of the second precursor layer 16 residing atop the first precursor layer 14 may not ever exit. In reality, with some reactions the kinetics favor the immediate formation of the first monolayer A-C 18, and the first monolayer 18 A-C may form immediately upon contact between the first precursor layer 14 and the second precursor material C-D as it is introduced to the reaction chamber. Thus, in this embodiment, the first monolayer 18 is formed at a rate that is determined by how fast the second precursor material C-D is introduced.

Therefore, without being bound by the specific kinetics of the various reactions that may be involved in a specific precursor pair, the final result of the atomic layer deposition as described above is the deposition of a single first monolayer 18 of a desired material. In the preferred embodiment, the first monolayer 18 is of an optically transmissive material. The method as described above is the basis for forming a structure for a strong phase shift mask substrate 10 that has finely tunable apparent optical path lengths, with associated finely tunable phase shifting ability.

Because the first monolayer 18 is deposited as a monolayer, the thickness of the first monolayer 18 is known, even before deposition, with a high degree of accuracy. Thus, the thickness of a layer formed by several deposition cycles of the first monolayer 18 is also known, by merely multiplying the thickness of a single monolayer 18 by the number of deposition cycles used to form the desired layer. In other words, the thickness of the resultant layer is determined by the number of deposition cycles completed, and not be the length of deposition time, the temperature of the chamber, the pressure of the chamber, the amount of energy introduced, or any one of a number of other variables that are relatively more difficult to control, especially across the surface of the substrate 12.

Thus, to deposit a layer of a desired thickness, an automated deposition tool is programmed to complete the desired process cycle a predetermined number of times. At the end of the programmed deposition, the thickness of the layer produced is already known with a high degree of accuracy. The above procedure can be used in an atomic layer deposition tool to produce layers at a growth rate of about thirty to ninety angstroms per minute, depending on the process.

The process by which the first monolayer 18 was formed may be repeated, either with another first monolayer 18 or with a monolayer of a different material, using a method similar to that as described above. As depicted in FIG. 4, a third precursor layer 20 is formed of a binary material, or in other words, a material that has two discernable components E-F. As mentioned above, the components E and F of the third precursor layer 20 may also represent a single atomic species each, or more complex molecules, or a combination of the two. Although it is preferred that the third precursor layer 20 is formed of a binary compound as depicted, in alternate embodiments the third precursor layer 20 is formed of a ternary or quaternary compound. Depending upon the composition of the resultant layer desired, the third precursor layer 20 may also be formed of a single component.

The third precursor layer 20 is preferably deposited on the first monolayer 18 such that the surface of the first monolayer 18 is completely saturated with the third precursor material. The third precursor may be introduced as a pure gas, or may be introduced in an evaporated form within a carrier gas. After the surface of the first monolayer 18 is completely saturated, the excess third precursor material is removed from the deposition chamber, such as by drawing a vacuum within the environment of the reaction chamber of the deposition tool.

A fourth precursor layer 22 is deposited on top of the third precursor layer 20, as depicted in FIG. 5. The fourth precursor layer 22 is preferably deposited according to a substantially similar method as that used for the third precursor layer 20. As depicted in FIG. 5, the fourth precursor layer 22 is formed of a binary material, or in other words, a material that has two discernable components G and H. The components G and H of the fourth precursor layer 22 may represent a single atomic species each, or more complex molecules, or a combination of the two. Although it is preferred that the fourth precursor layer 22 is formed of a binary compound as depicted, in alternate embodiments the fourth precursor layer 22 is formed of a ternary or quaternary compound. Depending upon the composition of the resultant layer desired, the fourth precursor layer 22 may also be formed of a single component.

The fourth precursor layer 22 is preferably deposited on the third precursor layer 20 such that each of the available bonding sites of the third precursor layer 20 is positioned with a corresponding molecule of the fourth precursor layer 22. The fourth precursor material is also introduced within the reaction chamber of the atomic layer deposition tool so used. As described above, the fourth precursor may be introduced as a pure gas, or may be introduced in an evaporated form within a carrier gas. After all of the bonding sites of the third precursor layer 20 are taken, the excess fourth precursor material is removed from the deposition chamber, such as by drawing a vacuum within the environment of the reaction chamber of the deposition tool.

As described above, the strong phase shift mask substrate 10 is once again subjected to some type of condition that drives the reaction kinetics between the third precursor layer 20 and the fourth precursor layer 22 to form the second monolayer 24 E-G as depicted in FIG. 6. Also as mentioned above, it is appreciated that the simplified discussion as presented in regard to the FIGS. 5 and 6 may describe an intermediate situation that does not actually exist. As before, the ordered arrangement of the fourth precursor layer 22 residing atop the third precursor layer 20 may not ever exit. In reality, with some reactions, the second monolayer 24 E-G may form immediately upon contact between the third precursor layer 20 and the fourth precursor material G-H as it is introduced to the reaction chamber. Thus, in this embodiment, the second monolayer 24 is formed at a rate that is determined by how fast the fourth precursor material G-H is introduced.

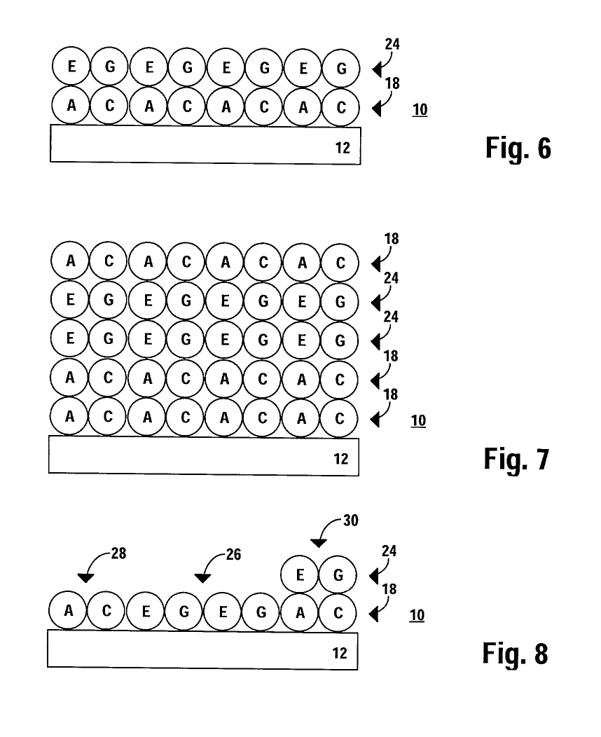

The first monolayer 18 and the second monolayer 24 can be deposited in an alternating manner and in varying numbers of monolayers, as represented in FIG. 7. It is appreciated that any number of additional monolayers, formed from different combinations of precursors, can also be deposited in conjunction with the first monolayer 18 and the second monolayer 24. In this manner, nanolaminates of extremely thin films can be formed, with predetermined and controllable thicknesses from about ten angstroms to about fifty angstroms. Although nanolaminates of greater thickness can be formed by this method, it is in these very thin ranges that the method enjoys it greatest advantage of controllability over alternate deposition methods.

The second monolayer 24 preferably has optical properties, or other properties, that are somewhat different than the optical properties of the first monolayer 18. The different properties of the first monolayer 18 and the second monolayer 24 are used in a variety of different ways, such as etch stops. For example, FIG. 8 depicts a first monolayer 18 that has been partially removed in region 26. A subsequently deposited second monolayer 24 then resides directly atop the substrate 12 in the region 26 where the first monolayer 18 was removed. As depicted in FIG. 8, the second monolayer 24 was etched from the region 28, but remains atop the first monolayer 18 in the region 30. In this manner, three different regions having three different optical properties are formed. In region 26, the radiation passes through the second monolayer 24 and the substrate 12. In region 28, the radiation passes through the first monolayer 18 and the substrate 12. In region 30, the radiation passes through the second monolayer 24, the first monolayer 18, and the substrate 12.

The various monolayers selected for deposition on the strong phase shift mask substrate 10 are selected based upon at least one of a number of different criteria. As mentioned herein, optical characteristics such as transmissivity, k₁, and scattering often play a very large part in the selection of the material, such as the precursors, used to form the monolayers. In addition, physical properties such as strain may also be very important in various embodiments.

It is appreciated that the number of monolayers of a given type that are deposited one upon another to form a given layer has been described very generally herein. Further, the number and arrangement of different monolayer materials has also been described very generally. In addition, the manner in which the various layers may be etched, patterned, and positioned has likewise been very generally described. In various actual embodiments, the number of layers, the number of different layers, the types of layers, and the patterning and positions of the layers is carefully predetermined and selected according to the specific optical properties desired. For example, these parameters as given above may be selected in one embodiment to fix very specific optical path lengths, so that the placement and degree of phase shift between adjacent fields is carefully set so at to produce the desired degree of phase interference between the fields, resulting in the finely tuned ability to pattern the sub wavelength features of an integrated circuit.

For example, region 28 as depicted in FIG. 8 may produce a predetermined phase shift in the radiation that is different from the predetermined phase shift produced by region 26. The difference in the phase shift between these two regions may cause a predetermined interference and resultant intensity extinction of the radiation between the two regions, which provides for patterning of the photoresist in a manner as described above. Similarly, region 30 may produce a predetermined phase shift in the radiation that is different from the predetermined phase shift produced by region 26. The difference in the phase shift between these two regions may cause a predetermined interference and resultant intensity extinction of the radiation between the two regions, which also provides for patterning of the photoresist in a manner as described above.

The different monolayers 18 and 24 may be used for more than just their optical properties. They may also be selected based upon their physical properties. For example, an underlying monolayer of a first type may be used as an etch stop in removing overlying monolayers of other types, and thus the monolayer of the first type provides a definite depth of etch during processing, protecting both the substrate and whatever monolayers that may be disposed below it.

The monolayers are most preferably etched using an anisotropic process, or in other words a highly directional etching method. For example, processes such as liquid chemical etching, gas phase etching, plasma based etching, sputter etching, ion beam etching, and molecular beam etching may be applied, as appropriate. In some embodiments, the various monolayers to be etched may be activated with a process that enhances the etchability of the monolayers to be removed. Most preferably, the activation process does not enhance the etchability of the monolayers that are not to be removed. The activation may be either a chemical or a physical treatment of the monolayers.

The above described procedures can be readily applied to blank substrates 12 to form new strong phase shift mask substrates. The binary masking patterns can be applied either before or after the phase shifting monolayers are deposited. For example, a binary chrome masking patterning can be deposited on the substrate 12 either prior to or after the formation of the optically transmissive phase shifting monolayers are created as described above. In yet a further embodiment, an existing strong phase shift mask, produced by an etching process or some other process, but which does not have the desired optical properties, could be modified by selectively depositing and etching monolayers according to the method described above, and thus be brought into conformance with the desired optical properties for the mask.

The foregoing description of preferred embodiments for this invention have been presented for purposes of illustration and description. They are not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as is suited to the particular use contemplated. All such modifications and variations are within the scope of the invention as determined by the appended claims when interpreted in accordance with the breadth to which they are fairly, legally, and equitably entitled.

What is claimed is:

1. A method of forming a strong phase shift mask substrate, the method comprising the steps of:
a. introducing a substrate having a surface into a deposition chamber, the substrate transmissive to electromagnetic radiation of a desired wavelength, b. introducing a first precursor having at least a first component and a second component, thereby covering the surface of the substrate with the first precursor to a thickness of one molecular layer of the first precursor, c. removing excess of the first precursor from the deposition chamber, d. introducing a second precursor having at least a third component and a fourth component, the second precursor attaching to the first precursor, e. removing excess of the second precursor from the deposition chamber, and f. reacting the first precursor with the second precursor to form a first monolayer of the first component and the third component on the surface of the substrate, the first monolayer operable to cause a first phase shift in the electromagnetic radiation of the desired wavelength.

2. The method of claim 1, further comprising etching the first monolayer to form a desired pattern in the first monolayer.

3. The method of claim 2, wherein the step of etching further comprises anisotropically etching the first monolayer.

4. The method of claim 2, wherein the step of etching further comprises etching the first monolayer using at least one of liquid chemical etching, gas phase etching, plasma based etching, sputter etching, ion beam etching, and molecular beam etching.

5. The method of claim 1, further comprising activating the first monolayer with a process that enhances the etchability of the first monolayer, but which does not enhance the etchability of the substrate.

6. The method of claim 5, wherein the activating process further comprises a chemical treatment.

7. The method of claim 5, wherein the activating process further comprises a physical treatment.

8. The method of claim 1, further comprising iteratively repeating steps (b) through (f) to form a first layer having a thickness of a predetermined number of monolayers.

9. The method of claim 8, further comprising iteratively repeating steps (b) through (f) until the first layer produces a desired phase shift in the electromagnetic radiation of the desired wavelength.

10. The method of claim 1, further comprising the steps of:
g. introducing a third precursor having at least a fifth component and a sixth component, h. removing excess of the third precursor from the deposition chamber, i. introducing a fourth precursor having at least a seventh component and an eighth component, the fourth precursor attaching to the third precursor, j. removing excess of the fourth precursor from the deposition chamber, and k. reacting the third precursor with the fourth precursor to form a second monolayer of the fifth component and the seventh component on the first monolayer, the second monolayer operable to cause a second phase shift in the electromagnetic radiation of the desired wavelength.

11. The method of claim 10, further comprising iteratively repeating steps (g) through (k) to form a second layer having a thickness of a predetermined number of monolayers.

12. The method of claim 11, further comprising iteratively repeating steps (g) through (k) until the second layer produces a desired phase shift in the electromagnetic radiation of the desired wavelength.

13. The method of claim 10, further comprising:
iteratively repeating steps (b) through (f) to form a first layer having a thickness of a predetermined number of monolayers, and iteratively repeating steps (g) through (k) to form a second layer having a thickness of a predetermined number of monolayers, where the first layer and the second layer produce a desired phase shift in the electromagnetic radiation of the desired wavelength.

14. The method of claim 10, further comprising repeating steps (b) through (f) as a first processing group and repeating steps (g) through (k) as a second processing group, where the first processing group and the second processing group are repeatedly performed in a predetermined sequence to form a composite layer on the substrate, where the composite layer has predetermined optical characteristics and predetermined etch characteristics.

15. The method of claim 14, further comprising selectively etching the composite layer between predetermined depositions of the first processing group and the second processing group.

16. The method of claim 14, further comprising selectively etching portions of the composite layer in predetermined areas of the strong phase shift mask substrate.

17. The method of claim 14, further comprising selectively etching portions of the composite layer in areas of the strong phase shift mask substrate that are determined to require such selective etching to produce the predetermined optical characteristics.

18. The method of claim 10, wherein the first monolayer has first optical characteristics and the second monolayer has second optical characteristics, and the first optical characteristics are different from the second optical characteristics.

19. The method of claim 10, wherein the second monolayer has etch characteristics that provide etch selectivity to the first monolayer.

20. The method of claim 1, wherein the desired wavelength is about 248 nanometers.

21. The method of claim 1, wherein the desired wavelength is about 193 nanometers.

22. The method of claim 1, wherein the desired wavelength is about 157 nanometers.

23. A strong phase shift mask substrate formed according to the method of claim 1.

24. A preexisting strong phase shift mask substrate modified according to the method of claim 1.

25. A method of forming a strong phase shift mask substrate, the method comprising the steps of:
a. introducing a substrate having a surface into a deposition chamber, the substrate transmissive to electromagnetic radiation of a desired wavelength, b. introducing a first precursor having at least a first component and a second component, thereby covering the surface of the substrate with the first precursor to a thickness of one molecular layer of the first precursor, c. removing excess of the first precursor from the deposition chamber, d. introducing a second precursor having at least a third component and a fourth component, the second precursor attaching to the first precursor, e. removing excess of the second precursor from the deposition chamber, f. reacting the first precursor with the second precursor to form a first monolayer of the first component and the third component on the surface of the substrate, the first monolayer operable to cause a first phase shift in the electromagnetic radiation of the desired wavelength, g. introducing a third precursor having at least a fifth component and a sixth component, the third precursor covering the surface of the first monolayer, h. removing excess of the third precursor from the deposition chamber, i. introducing a fourth precursor having at least a seventh component and an eighth component, the fourth precursor attaching to the available bonding sites on the third precursor, j. removing excess of the fourth precursor from the deposition chamber, k. reacting the third precursor with the fourth precursor to form a second monolayer of the fifth component and the seventh component on the first monolayer, the second monolayer operable to cause a second phase shift in the electromagnetic radiation of the desired wavelength, and l. selectively etching portions of the first monolayer and selectively etching portions of the second monolayer to form regions having desired phase shift characteristics.

26. A strong phase shift mask substrate, comprising:
a substrate, the substrate transmissive to electromagnetic radiation of a desired wavelength, and an optically transmissive layer, the optically transmissive layer formed of a predetermined number of at least one type of individually deposited monolayers, where the optically transmissive layer causes a predetermined phase shift in the electromagnetic radiation of the desired wavelength.
